(19) United States
(12) Patent Application Publication
(10) Pub. No.: US 2012/0018726 A1
(43) Pub. Date: Jan. 26, 2012

(54) SEMICONDUCTOR WAFER AND METHOD FOR MANUFACTURING SEMICONDUCTOR DEVICE

(75) Inventors: Yoshihiro Nakagawa, Tokyo (JP); Koichi Nose, Tokyo (JP); Koichiro Noguchi, Tokyo (JP); Masamoto Tago, Tokyo (JP); Shinichi Uchida, Kanagawa (JP); Yoshiyuki Sato, Kanagawa (JP)

(73) Assignee: NEC CORPORATION AND RENESAS ELECTRONICS CORPORATION

(21) Appl. No.: 13/258,884

(22) PCT Filed: Mar. 23, 2010
(86) PCT No.: PCT/JP2010/054918

§ 371 Date: Sep. 22, 2011

(30) Foreign Application Priority Data
Mar. 24, 2009 (JP) 2009-072508

(51) Int. Cl. H01L 23/48; H01L 21/768

(52) U.S. Cl. 257/48; 438/18; 257/E23.01; 257/E21.59

(57) ABSTRACT

A semiconductor wafer in which a plurality of regions, designed to become semiconductor chips are provided in a matrix array with interposition of a dicing line(s) respectively separating the regions. The semiconductor wafer comprises: a plurality of test pads provided in an area(s) of the semiconductor wafer disposed between the semiconductor chips, inclusive of the dicing line(s); an inter-test pad interconnect(s) provided in parallel with the test pads in the area(s) of the semiconductor wafer disposed between the regions to become semiconductor chips; the inter-test pad interconnect(s) being connected to the test pads; and an inter-chip interconnect that interconnects at least two of the regions designed to become semiconductor chips; the inter-test pad interconnect being electrically connected to the inter-chip interconnect.

### TECHNICAL FIELD

### Reference to Related Application

This application is based upon and claims the benefit of the priority of Japanese patent application No. 2009-072508 filed on Mar. 24, 2009, the disclosure of which is incorporated herein in its entirety by reference thereto.

This invention relates to a semiconductor wafer and a manufacturing method for a semiconductor device. More particularly, it relates to a semiconductor wafer in which a plurality of semiconductor chips may be tested in parallel and to a method for manufacturing a semiconductor device that uses the above mentioned semiconductor wafer in an intermediate step in the course of a manufacturing process thereof.

### BACKGROUND ART

In a general manufacturing process for a semiconductor device, functional tests are conducted in a wafer state in order to test the functions of a semiconductor chip formed on the semiconductor wafer before moving to a subsequent assembling step. This test in the wafer state is carried out as follows. In the test, a test device, called a probe card, provided with a plurality of probe needles, is used. A test electrical signal, generated by a device called a tester, is applied to the semiconductor chip. An operation result is inputted to the tester and calculated by the tester, using the probe card.

Recently, with increases of an element number and the advancement of a function built in of a semiconductor chip, test contents become complicated, test time increase, and it has led to increase of the test cost of a semiconductor device. To cope with the situation, a plurality of semiconductor chips is tested simultaneously in parallel, thereby reducing the test time per chip as well as test costs.

However, with miniaturization of the circuitry on the semiconductor chip, the area as well as the pitch of the signal input/output pads is reduced to render probe needle signal input/output operations difficult, thus imposing limitations on the number of the chips that may be tested simultaneously.

With this in view, the following technique has been proposed in order to increase the number of semiconductor chips tested simultaneously. In this technique, there are provided inter-chip interconnects that interconnect input/output pads of respective semiconductor chips provided on a semiconductor wafer which is in a state prior to segmentation into a plurality of individual semiconductor chips. It is possible with this technique to reduce the number of signals that may be delivered to or output by the probe card or the number of power supplies while increasing the number of the semiconductor chips that may be tested simultaneously. FIG. 5 corresponds to FIG. 2 of Patent Document 1. Referring to FIG. 5, showing a semiconductor device of Patent Document 1, a plurality of input/output pads of the semiconductor chips are connected one to another via interconnects. A plurality of input/output pads for test signals is provided on the rim of the semiconductor wafer to carry out the test. After finishing the test, the semiconductor wafer is severed into a plurality of semiconductor chips, at the same time as the interconnects that connected the semiconductor chips one to another are cut off. Note that each input/output pad of the semiconductor chip is connected at this time to at least one of the test pads. It is thus possible to reduce the number of signals used for inputting/outputting at the test time in comparison with the case where the test was conducted using a probe card for each of the input/output pads of each semiconductor chip. Consequently, the number of the semiconductor chips to be tested simultaneously may be increased, thereby reducing the test time and the test costs.

In Patent Document 2, there is shown a semiconductor wafer in which test pads common to neighboring chip regions are provided in a scribe line area.

### PRIOR ART DOCUMENT

### Patent Document

### Patent Document 1:

U.S. Pat. No. 5,594,273

### Patent Document 2:

Japanese Unexamined Patent Application Publication Kokai Publication No. JP-P2004-342725A

### SUMMARY OF THE INVENTION

### Problems to be Solved by the Invention

The following analysis is afforded by the present invention. In the semiconductor wafer, disclosed in Patent Document 1, test pads (54 to 59 in FIG. 5) are provided just on the wafer rim part. Hence, the test pads are spaced apart a marked distance from semiconductor chips arranged near the center of the wafer, as a result of which parasitic resistance of the inter-chip interconnects that interconnect the input/output pads of the semiconductor chips is increased. It is thus not possible to obtain desired input/output signals.

On the other hand, in Patent Document 2, it is just the neighboring chip regions that are able to share the test pad, so that it is not possible to test larger numbers of semiconductor chips in parallel.

It is therefore an object of the present invention to provide a semiconductor wafer in which test time for the semiconductor wafer in its entirety in the course of the semiconductor wafer manufacturing process may be shortened to render it possible to reduce test costs. It is also aimed at by the present invention to provide a method for manufacturing a semiconductor device employing the above mentioned semiconductor wafer.

### Means to Solve the Problems

In a first aspect of the present invention, there is provided a semiconductor wafer in which a plurality of regions, designed to become semiconductor chips, are provided in a matrix array with interposition of a dicing line respectively separating the regions. The semiconductor wafer includes a plurality of test pads provided in an area(s) of the semiconductor wafer disposed between the semiconductor chips, the area being inclusive of the dicing line(s). The semiconductor wafer also includes an inter-test pad interconnect(s) provided in parallel with the test pads in the area(s) of the semiconductor wafer disposed between the regions to become semiconductor chips. The inter-test pad interconnect(s) is connected to the test pads. The semiconductor wafer further includes an inter-chip interconnect that interconnects at least two of the regions designed to become semiconductor chips. The inter-test pad interconnect is electrically connected to the inter-chip interconnect.

In a second aspect of the present invention, there is provided a method for manufacturing a semiconductor device including manufacturing the above mentioned semiconductor wafer. The method also includes conducting a test on the semiconductor wafer using the test pads, and dividing the semiconductor wafer into a plurality of semiconductor chips not containing the test pads and the inter-test pad interconnects. The method further includes assembling the semiconductor chip concluded to be a regular product by the step of conducting the test to complete a semiconductor device.

### Meritorious Effects of the Invention

According to the present invention, there may be provided a semiconductor wafer and a manufacturing method for a semiconductor device, in which it is possible to reduce the test time for the semiconductor wafer in its entirety to reduce the test cost.

### BRIEF DESCRIPTION OF THE DRAWINGS

FIG. 1 is a plan view of an entire semiconductor wafer according to an Example of the present invention.

FIG. 2 is an enlarged plan view showing essential portions of the semiconductor wafer according to the Example of the present invention.

FIGS. 3A, 3B and 3C are cross-sectional views taken along lines AA′, BB′ and CC′ of FIG. 2, respectively.

FIGS. 4A, 4B and 4C are cross-sectional views taken along lines DD′, EE′ and FF′ of FIG. 2, respectively.

FIG. 5 is a cross-sectional view showing a conventional semiconductor wafer of Patent Document 1 in its entirety.

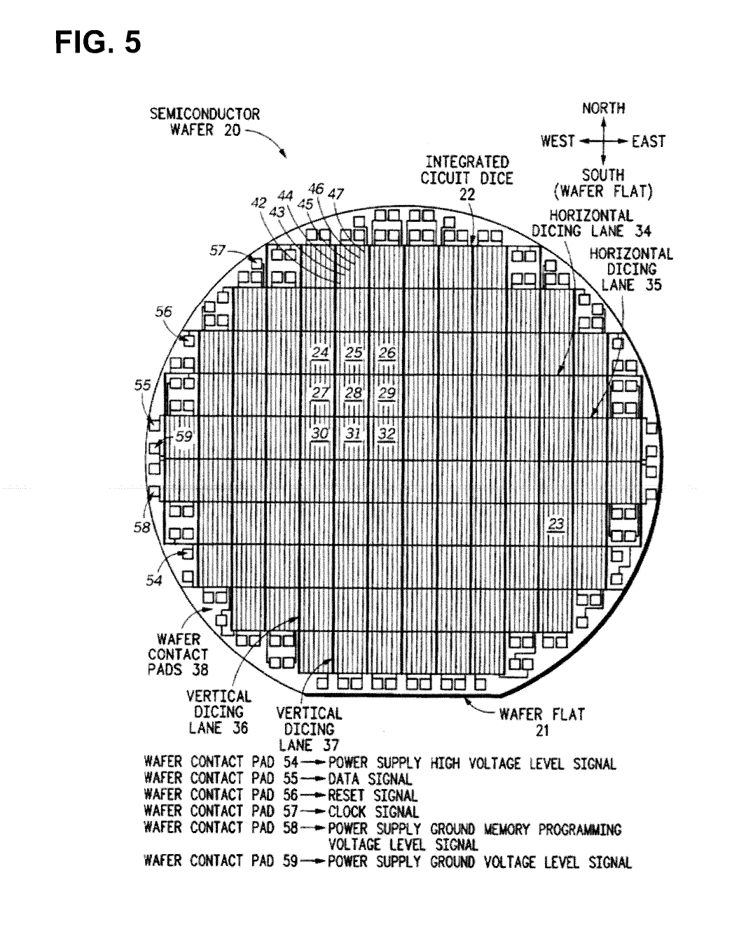

### MODES FOR CARRYING OUT THE INVENTION

Shown below are possible or preferred modes of the present invention:

### (Mode 1)

As stated in the first aspect.

### (Mode 2)

The inter-chip interconnect is preferably laid in a direction of crossing the inter-test pad interconnect at right angles.

### (Mode 3)

The test pads are preferably arranged adjacent to a row and/or a column where the number of the rows or columns of the regions, designed to become the semiconductor chips, is of a maximum value.

### (Mode 4)

Preferably, the test pads are arranged in a row and/or a column passing substantially through the center of the semiconductor wafer.

### (Mode 5)

Preferably, the inter-test pad interconnect and the inter-chip interconnect, connected to the inter-test pad interconnect, are formed at least an interconnect layer of the same level, such that the inter-test pad interconnect and the inter-chip interconnect are directly connected layer-wise to each other without the interposition of contacts.

### (Mode 6)

Preferably, a plurality of the inter-test pad interconnects are laid as a plurality of interconnect layers one on top of another with interposition of at least one insulation layer in-between, and wherein the inter-test pad interconnects are connected to respective different ones of the test pads and to respective different interconnect layers of the inter-chip interconnect.

### (Mode 7)

As stated in the second aspect.

### (Mode 8)

The inter-test pad interconnects and the inter-chip interconnects formed by interconnect layer(s) of the respective same level(s) as those of the inter-test pad interconnects for connection directly to the inter-test pad interconnects are preferably formed using respective different exposure masks.

### (Mode 9)

The mask used for exposure of the inter-test pad interconnects by light is preferably used in common in manufacturing a plurality of semiconductor devices of different chip sizes.

### (Mode 10)

The test pads are preferably provided at common locations for a plurality of semiconductor devices with different chip sizes and, in the testing step, the testing is preferably carried out using a common probe card for a plurality of semiconductor devices having different chip sizes.

An exemplary embodiment of the present invention will now be described by referring to the drawings as necessary. Note that the drawings and reference numerals used therein are only by way of illustration of the exemplary embodiment and are not intended to limit variations of the exemplary embodiment of the present invention.

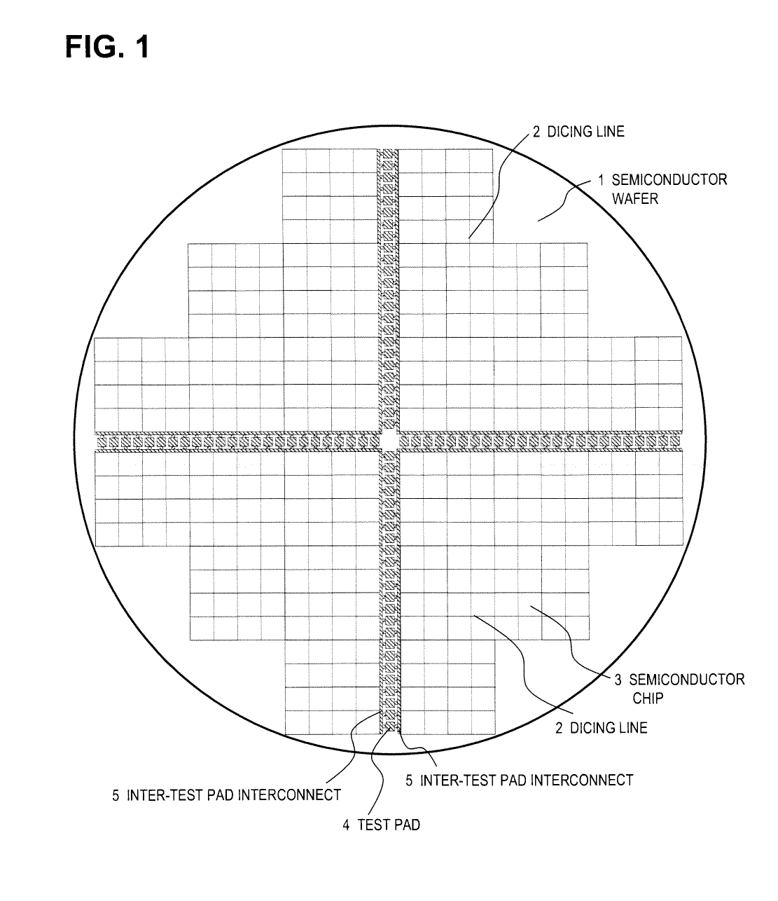

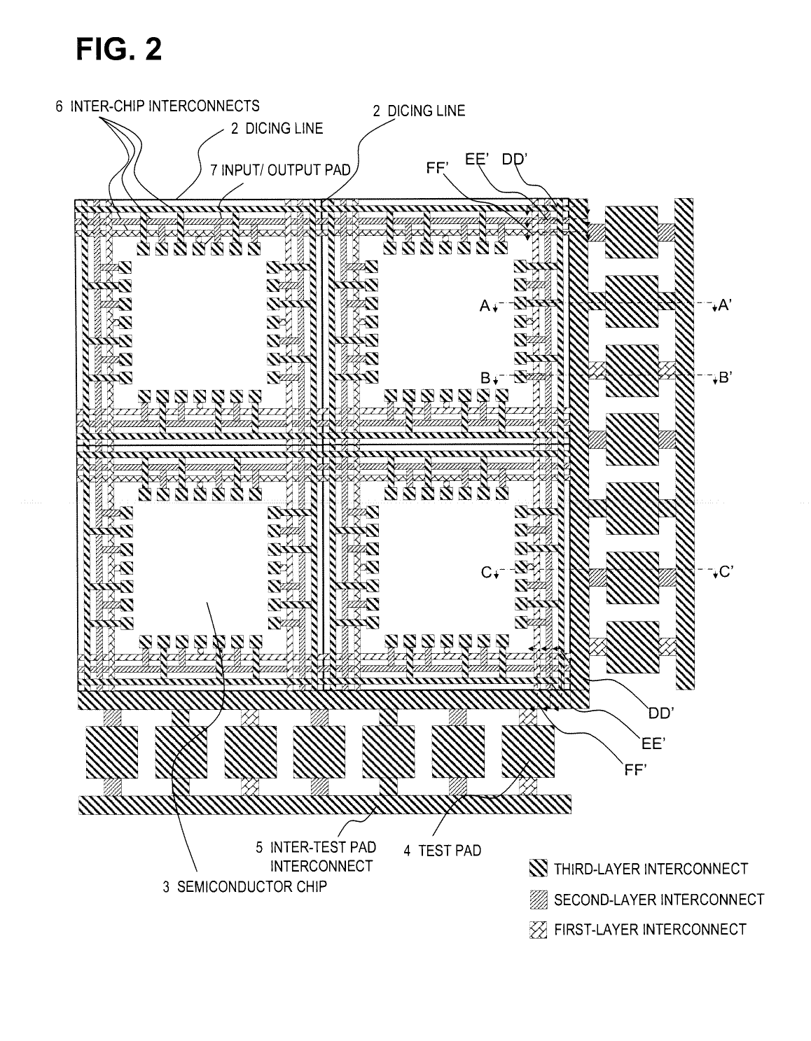

A semiconductor wafer 1 of an exemplary embodiment of the present invention is a semiconductor wafer 1 in which a plurality of regions, designed to become semiconductor chips 3, are provided in a matrix array with interposition of dicing lines respectively, as shown in FIGS. 1 and 2, for instance. The semiconductor wafer includes a plurality of test pads 4 provided in an area(s) of the semiconductor wafer disposed between the semiconductor chips, inclusive of the dicing line(s) 2. The semiconductor wafer also includes an inter-test pad interconnect(s) 5 provided in parallel with the test pads in the area of the semiconductor wafer designed to become semiconductor chips 3. The inter-test pad interconnect is connected to the test pads 4. The semiconductor wafer further includes an inter-chip interconnect 6 that interconnects at least two of the regions designed to become semiconductor chips 3. The inter-test pad interconnects 5 are electrically connected to the inter-chip interconnect 6. In the above mentioned configuration, a plurality of semiconductor chips may be tested in parallel as increase in the area for wafer testing is suppressed to a smallest value possible and as connection impedance to the semiconductor chips is kept sufficiently low.

A semiconductor wafer 1 of an exemplary embodiment is arranged on a row and/or column substantially passing through the center of the semiconductor wafer 1, as shown for example in FIG. 1. That is, the test pads 4 may be arranged along a row through the center portion of the semiconductor wafer, or along a column through the center portion of the semiconductor wafer 1. If, in particular, the test pads are arranged along both the row and the column, as shown in FIG. 1, the distance as far as the semiconductor chip remotest from the test pads arrayed along the row or the column is equal to 1/√ 2 of the radius of the semiconductor wafer 1. It is thus possible to reduce the interconnect resistance as compared to the case of providing the test pads along the outer circumferential rim of the semiconductor wafer.

In the semiconductor wafer 1 of an exemplary embodiment, a plurality of inter-test pad interconnects 5 are laid in a plurality of interconnect layer(s), one on top of others, with the interposition of insulation layers in-between, as shown in FIGS. 2 to 4. The inter-test pad interconnects are coupled layer-wise to respective different ones of the test pads and to the inter-chip interconnects. It is thus possible to suppress increase in the area for wafer testing to as small a value as possible and to conduct parallel testing for a plurality of the semiconductor chips in a state of sufficiently low connection impedance to the respective semiconductor chips.

A method for manufacturing a semiconductor device according to an exemplary embodiment of the present invention includes manufacturing the semiconductor wafer 1, and conducting a test on the semiconductor wafer 1 using test pads 4. The method also includes splitting the semiconductor wafer into a plurality of semiconductor chips not containing the test pads 4 or inter-test pad interconnects 5, and assembling the semiconductor chips 3 concluded to be regular products in the test process to complete a semiconductor device.

In the method for manufacturing a semiconductor device according to an exemplary embodiment of the present invention, the inter-test pad interconnects and the inter-chip interconnects formed by interconnect layer(s) of the respective same level(s) as those of the inter-test pad interconnects for connection directly to the inter-test pad interconnects are formed using respective different exposure masks. In general, exposure by light of a given pattern to a semiconductor wafer is carried out using a mask having formed thereon a pattern of an area smaller than that of the entire semiconductor wafer. Exposure by light is repeated as the mask is shifted in its position to form pattern repetition over the entire surface of the semiconductor wafer. However, exposure by light of the inter-test pad interconnects 5 is not possible with such pattern repetition. Thus, for example, the inter-test pad interconnects 5 are exposed by light using a mask that allows the entire semiconductor wafer to be exposed by light at a time. In the present exemplary embodiment, interconnection of the inter-test pad interconnects and the inter-chip interconnects is formed on the respective interconnect layers of the same levels. Hence, the inter-test pad interconnects and the inter-chip interconnects may be interconnected even in case position registration of the two interconnects for light exposure is low in accuracy.

Note that, in the manufacturing method for the semiconductor device according to an exemplary embodiment, the mask used for exposure by light of the inter-test pad interconnects may be used in common in manufacturing a plurality of semiconductor devices with different chip sizes. Viz., it is sufficient that the laying positions of the inter-test pad interconnects are decided at the outset, for example, it is sufficient that it is determined at the outset that the test pads and the inter-test pad interconnects are placed on the row and the column passing through the center portion of the semiconductor wafer. In this case, a common mask may be used even if the semiconductor devices are of differing chip sizes, insofar as exposure by light of the inter-test pad interconnects is concerned. An Example of the present invention will now be described in detail with reference to the drawings.

### EXAMPLE 1

FIG. 1 depicts a plan view showing a semiconductor wafer 1 of Example 1 in its entirety. The semiconductor wafer 1 includes a semiconductor wafer substrate, as an underlying member, on which there is formed a matrix array of a plurality of regions designed to become a semiconductor chip 3 later on. The semiconductor chips 3 are separated from one another by a plurality of dicing lines 2 extending vertically and horizontally. A plurality of test pads 4 are arrayed side-by-side in a row direction and in a column direction of a matrix so as to pass through the center of the semiconductor wafer 1. The test pads 4 are arrayed in an area disposed between the semiconductor chips 3, arrayed in the matrix, inclusive of the dicing lines 2. An inter-test pad interconnect (wiring) 5 is arranged adjacent to and in parallel with the test pads 4 in turn arrayed side-by-side. A plural number of the test pads 4 are arranged for use with power supplies, another plural number of the test pads 4 are arranged for use with grounding and a further plural number of the test pads 4 are arranged for use with input/output signals, respectively depending to the assigned usage. The inter-test pad interconnect (wiring) 5 is connected to associated ones of the test pads to interconnect those test pads, respectively, to which are coupled the same signals or the same power supplies.

FIG. 2 depicts an enlarged view showing mid left upper part of the semiconductor wafer also shown in FIG. 1. Referring to FIG. 2, a plurality of input/output pads 7 for connecting to the power supplies, to the ground or to the input/output signals are provided in a region which later functions as the semiconductor chip 3. An inter-chip interconnects 6 are provided each to interconnect the input/output pads 7 disposed at the neighboring distances. It is via these inter-chip interconnects 6 that the power supplies, ground or the input/output signals of the same sorts of the semiconductor chips are interconnected with themselves. The inter-chip interconnects 6 are arranged in a manner of crossing the dicing line(s) 2 to interconnect the semiconductor chips astride the dicing line(s) 2.

The inter-chip interconnects 6 are formed in three interconnect layers, namely first to third interconnect layers, as is the case with the inter-test pad interconnects. The inter-chip interconnect 6 is connected to an associated one of a plurality of the inter-test pad interconnects 5. At least the portions of the inter-chip interconnect 6 that are connected to the inter-test pad interconnect(s) 5 are formed in an interconnect layer of the same levels as that of the inter-test pad interconnect 6 so as to be connected to the inter-test pad interconnect without interposition of contacts. Also, the portions of the inter-chip interconnect 6, connected to the inter-test pad interconnect 5, are laid in a direction to cross the inter-test pad interconnect at right angles.

Suppose that a semiconductor wafer is being manufactured using a routine manufacturing process employing a stepper (reduction projection type exposure apparatus). In this case, a mask that exposes by light an area smaller than the entire semiconductor wafer surface is used, and exposure by light is carried out repeatedly as the mask position is shifted, thereby generating regular pattern repetition on the entire semiconductor wafer surface. However, the test pads 4 as well as the inter-test pad interconnects 5 are not of a regular pattern provided on the entire semiconductor wafer surface. Therefore, if the same routine light exposure method as that used for a pattern in the semiconductor chip 3 including the inter-chip interconnects 6 is used, the patterns comprised of the test pads and the inter-test pad interconnects could not be generated. It is thus necessary to generate the inter-test pad interconnects 5 and the test pads 4 by some other light exposure method. It would then be necessary to provide for position registration between the inter-test pad interconnects 5 and a plurality of the inter-chip interconnects 6 connected to the inter-test pad interconnects 5. In the present Example, the inter-chip interconnects 6 and the inter-test pad interconnects 5 are laid in a direction of crossing each other with the use of the interconnect layers of the same levels. It is thus unnecessary to provide e.g., contacts for connecting the two interconnects, such that connection of the two interconnects is not of a problem even in case of low accuracy in position registration.

By connecting input/output pads 7 within the semiconductor chips 3 to the test pads 4, using the inter-test pad interconnects 5 and the inter-chip interconnects 6, the length of an interconnect(s) from the test pads 4 to a semiconductor chip located remotest from the test pads 4 may be minimized. Referring to FIG. 1, there is provided a plural number of test pads connected to the same signal. It is thus sufficient to connect a semiconductor chip 3 in question to the nearest one of the test pads 4 that are arrayed in columns and rows so as to pass through the center portion of the semiconductor wafer 1. Consequently, the distance from the test pad 4 to the remotest semiconductor chip 3 is 1/√ 2 of the radius of the semiconductor wafer. In case the test pads 4 are provided on a perimeter of the semiconductor wafer 1, as in Patent Document 1, the distance up to the semiconductor chip disposed at the center of the semiconductor wafer remotest from any of the test pads is equal to the radius of the semiconductor wafer. By arranging the test pads as shown in FIG. 1, the distance may be reduced to 1/√ 2, thus enabling reduction in the interconnect resistance from the test pad 4 to the semiconductor chip.

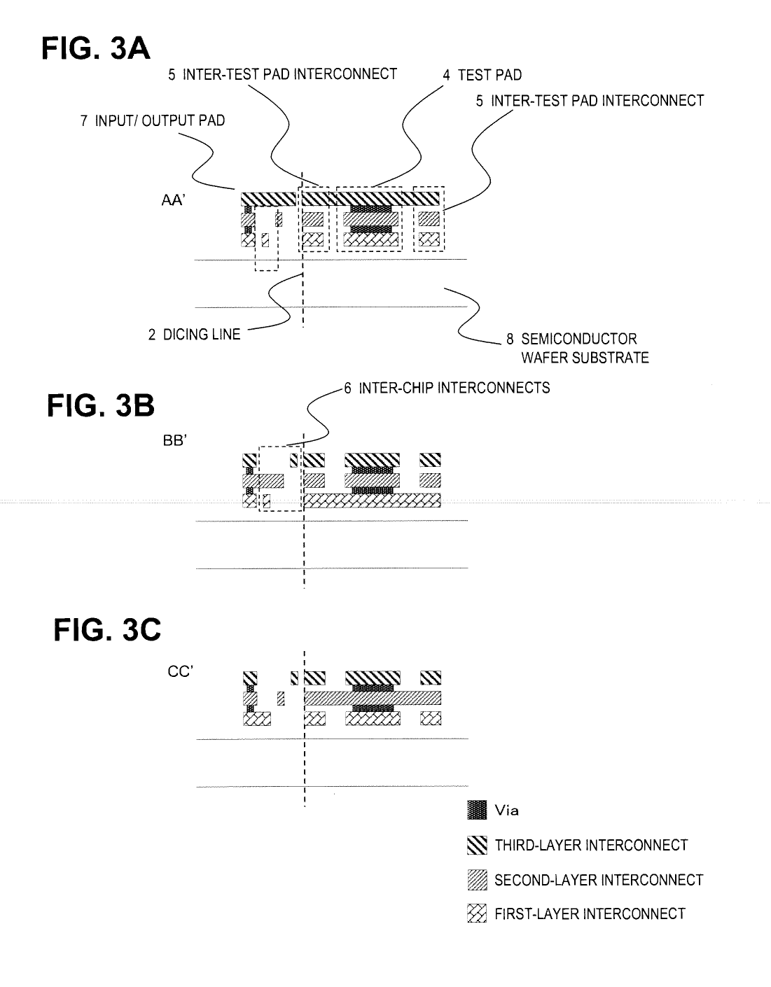

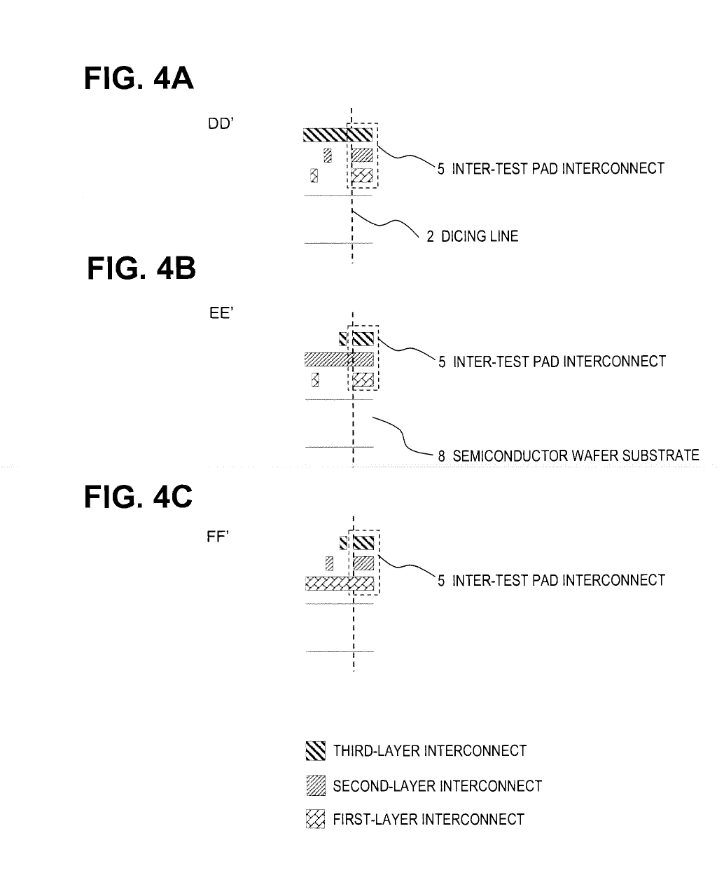

FIGS. 3A-3C and 4A-4C are cross-sectional views of FIG. 2. Specifically, FIGS. 3A, 3B and 3C are cross-sectional views taken along lines AA′, BB′ and CC′ of FIG. 2, respectively. FIGS. 4A, 4B and 4C are cross-sectional views taken along lines DD′, EE′ and FF′ of FIG. 2, respectively. In FIGS. 3A-3C and 4A-4C, interconnects of the first to third interconnect layers are formed on a semiconductor wafer substrate 8. Note that a plurality of transistors, not shown, are formed on the surface of the region of the semiconductor wafer substrate which later is to become the semiconductor chip 3.

Referring to FIGS. 3A-3C and 4A-4C, the inter-test pad interconnect 5 is laid in the form of three-layer interconnects, viz., interconnects of the first to third layers, as is the inter-chip interconnects 6. It is noted however that, in forming the inter-test pad interconnect(s) 5, three separate inter-test pad interconnects 5, connected to respective different ones of the test pads, are laid one on top of others as three layers in the same chip region. The inter-chip interconnects 6 are connected layer-wise to the inter-test pad interconnects 5 via interconnect layers of the respective same levels.

In the present Example, the inter-test pad interconnect 5 is composed of the three interconnect layers. Hence, the input/output pads 7 of the semiconductor chips and the test pads may be interconnected by the three-layered inter-test pad interconnect to conduct three signal sorts, namely the power supplies, ground and the input/output signal. However, by increasing the number of the interconnect layers, more signals may be delivered (or tested) from the test pads. An area of interconnection of the inter-chip interconnect and the inter-test pad interconnect may be split into a plurality of zones to increase the sorts of the test signals or the power supplies for tests.

It is possible to preset the positions of the inter-test pad interconnects 5 or the test pads 4, or further the interconnect layers used for the inter-test pad interconnects 5, and to layout the inter-chip interconnects 6 in accordance with the so preset positions or the interconnect layers. By so doing, the laying positions and the interconnect layers of the inter-test pad interconnects 5 and the test pads 4 may be used in common in connection with a plurality of semiconductor devices with different chip sizes. If such common use is possible, masks for exposure by light of the inter-test pad interconnects 5 and the test pads 4 or a probe card to be connected to the test pads may be used in common in connection with the semiconductor devices with different chip sizes.

The method for testing a semiconductor device according to the present invention will now be described. When a given test pad 4 inputs a test signal, the test signal may be delivered, via the inter-test pad interconnect 5 connected to the test pad 4 and via the inter-chip interconnect 6, to a plurality of semiconductor chips connected to the inter-chip interconnect 6. The results of the operations of the semiconductor chips 3 are sent via the inter-chip interconnect 6 and the inter-test pad interconnect 5 to the test pad 4 for allowing confirming the operation of the respective semiconductor chips 3. That is, delivery to and outputting from the multiple semiconductor chips may be achieved using a smaller number of test pads. In addition, the multiple semiconductor chips may be tested simultaneously, thus allowing shortening the test time.

Although the total of the signals used for testing may be delivered to or output from the test pads 4, it is unnecessary that the total of the test signals is so delivered or output. Even if the test pad 4 is used for at least one of the test signals, the cost reducing effect is apparent. For example, only a power supply signal, out of the multiple signals used for testing, may be delivered to the test pad 4, while the test signals and the signals of the results of the operations may be delivered to or output from the input/output pads 7 loaded on each semiconductor chip 3, as in conventional testing of semiconductor devices. In addition, the test signals and the signals of the results of the operations may be delivered and output using a signal transmitting technique exploiting electro-magnetic induction.

In Example 1, the input/output pads 7 and the inter-chip interconnects 6 are directly connected together, as shown in FIG. 2. However, such direct connection may not be necessary. For example, a control circuit controlling the connection between the input/output pads 7 and the inter-chip interconnects 6 may be introduced between the input/output pads 7 and the inter-chip interconnects 6. A regulator circuit that generates a desired voltage may also be so introduced.

In the Example, described above, in which a plural number of the semiconductor chips are tested simultaneously, the test time may be reduced, while the distance from the test pads 4 to the respective semiconductor chips 3 may be shortened. Consequently, the inter-test pad interconnects 5 and the inter-chip interconnects 6 may be reduced in thickness, and hence the number of the semiconductor chips 3 that may be loaded on the semiconductor wafer 1 may be increased, with the result that the manufacturing cost of the semiconductor chip 3 may be decreased.

In addition, the inter-chip interconnects 6 and the inter-test pad interconnects 5 are connected layer-wise by interconnects of the interconnect layers of the same levels crossing each other. Therefore, even in case the inter-chip interconnects 6 and the inter-test pad interconnects 5 are separately exposed by light to form a pattern, it is possible to prevent connection failure between the inter-chip interconnects 6 and the inter-test pad interconnects 5 otherwise caused by variations brought about during fabrication of semiconductor chip.

It is moreover possible to prevent connection failure between the input/output pads of the semiconductor chips.

Moreover, the test pad positions may be decided without dependency upon the sort or size of the semiconductor chip manufactured. Hence, the probe card, used in delivering signals to or outputting them from the test pads, may be used in common, thus allowing the cost to be reduced.

In addition, since the test pads 4 are connected to the inter-test pad interconnects 5, connection to the semiconductor chips may be made in parallel via the test pads 4, thus allowing reducing the number of non-regular products otherwise produced due to contact failure with the probe needles. Since parallel connection may be established from the probe card to respective semiconductor chips via the test pads 4 and the inter-test pad interconnects 5, it is also possible to reduce the connection resistance.

The foregoing description has been made of an Example of the present invention. However, the present invention is not limited to this Example, such that a variety of modifications and corrections that may occur to those skilled in the art is naturally included within the scope of the invention.

### INDUSTRIAL UTILIZABILITY

The present invention may be applied not only to a case where a semiconductor device is presented on the marketplace as a finished product, but also to a case where it is presented as a semi-finished product, that is, as a semiconductor wafer prior to splitting into a plural number of semiconductor chips.

The particular exemplary embodiments or examples may be modified or adjusted within the gamut of the entire disclosure of the present invention, inclusive of claims, based on the fundamental technical concept of the invention. Further, a variety of combinations or selection of devices disclosed herein may be made within the scope of the claims.

### EXPLANATION OF SYMBOLS

1: semiconductor wafer
2: dicing line
3: semiconductor chip
4: test pad
5: inter-test pad interconnect
6: inter-chip interconnect
7: input/output pad
8: semiconductor wafer substrate

1. A semiconductor wafer in which a plurality of regions, designed to become semiconductor chips are provided in a matrix array with interposition of a dicing line(s) respectively separating said regions; the semiconductor wafer comprising:
a plurality of test pads provided in an area(s) of the semiconductor wafer disposed between the semiconductor chips, said area being inclusive of said dicing line(s);
an inter-test pad interconnect(s) provided in parallel with said test pads in said area(s) of said semiconductor wafer disposed between said regions to become semiconductor chips, said inter-test pad interconnect(s) being connected to said test pads; and
an inter-chip interconnect that interconnects at least two of said regions designed to become semiconductor chips; said inter-chip interconnect being electrically connected to said inter-test pad interconnect.

2. The semiconductor wafer according to claim 1, wherein
said inter-chip interconnect is laid in a direction of crossing said inter-test pad interconnect at right angles.

3. The semiconductor wafer according to claim 1, wherein
said test pads are arranged adjacent to a row and/or a column of said matrix where a number of the rows or columns of said regions designed to become the semiconductor chips, is maximum.

4. The semiconductor wafer according to claim 1, wherein
said test pads are arranged in a row or a column of said matrix passing substantially through a center of said semiconductor wafer.

5. The semiconductor wafer according to claim 1, wherein
said inter-test pad interconnect and said inter-chip interconnect, connected to said inter-test pad interconnect, are formed by at least an interconnect layer of the same level, such that said inter-test pad interconnect and said inter-chip interconnect are directly connected to each other without interposition of contacts.

6. The semiconductor wafer according to claim 1, wherein
a plurality of said inter-test pad interconnects are laid as a plurality of interconnect layers one on top of another with interposition of at least one insulation layer in-between, and wherein
said inter-test pad interconnects are connected to respective different ones of said test pads and to respective different interconnect layers of said inter-chip interconnect.

7. A method for manufacturing a semiconductor device comprising:
manufacturing the semiconductor wafer according to claim 1;
conducting a test on the semiconductor wafer using said test pads; and
dividing said semiconductor wafer into a plurality of semiconductor chips not containing said test pads and said inter-test pad interconnects followed by assembling the semiconductor chip concluded to be a regular product by said testing step to complete a semiconductor device.

8. The method for manufacturing a semiconductor device according to claim 7, wherein
said inter-test pad interconnects and the inter-chip interconnects, formed by interconnect layer(s) of the respective same level(s) as those of the inter-test pad interconnects for connection directly to the inter-test pad interconnects, are formed using respective different exposure masks.

9. The method for manufacturing a semiconductor device according to claim 8, wherein
said mask used for exposure of said inter-test pad interconnect by light is used in common in manufacturing a plurality of semiconductor devices of different chip sizes.

10. The method for manufacturing a semiconductor device according to claim 7, wherein
said test pads are provided at common locations for a plurality of semiconductor devices with different chip sizes; and wherein,
in said testing step, the testing is carried out using a common probe card for a plurality of semiconductor devices having different chip sizes.
